(19) United States
(12) Patent Application Publication
(10) Pub. No.: US 2024/0304574 A1
(43) Pub. Date: Sep. 12, 2024

(54) SEMICONDUCTOR DEVICE AND SEMICONDUCTOR DEVICE MANUFACTURING METHOD

(71) Applicant: Mitsubishi Electric Corporation, Tokyo (JP)

(72) Inventors: Yohei TORII, Tokyo (JP); Manabu YOSHINO, Tokyo (JP); Yasuo YAMAGUCHI, Tokyo (JP); Toshihiro IMASAKA, Tokyo (JP); Atsushi ITO, Tokyo (JP)

(73) Assignee: Mitsubishi Electric Corporation, Tokyo (JP)

(21) Appl. No.: 18/392,757

(22) Filed: Dec. 21, 2023

(30) Foreign Application Priority Data
Mar. 6, 2023 (JP) 2023-033604

(51) Int. Cl. H01L 23/00

(52) U.S. Cl. CPC H01L 24/05; H01L 24/03; H01L 2224/022; H01L 2224/03; H01L 2224/04042; H01L 2224/05582

(57) ABSTRACT

A semiconductor device includes: a substrate; a breakdown voltage holding insulating film; an element portion including a lower element and an upper element; a lead-out wire; a first electrode pad; a second electrode pad being one end portion of the upper element; and a top layer protective film covering the upper element so that the second electrode pad is exposed from a second contact hole. The breakdown voltage holding insulating film and the top layer protective film extend to a region outside the first electrode pad in a direction of extension of the lead-out wire. An electrically conductive pad double stack portion is disposed on an upper surface of the second electrode pad. The top layer protective film covers a peripheral portion of the pad double stack portion.

### BACKGROUND OF THE INVENTION

### Field of the Invention

The present disclosure relates to semiconductor devices and semiconductor device manufacturing methods.

### Description of the Background Art

As a conventional structure, Japanese Patent Application Laid-Open No. 2008-218121 discloses a signal transmission device including a breakdown voltage holding insulating film that is disposed on a side of an upper surface of a substrate, a lower element that is disposed in the breakdown voltage holding insulating film and is spiral in top view, an upper element that is disposed in an upper surface of the breakdown voltage holding insulating film and is spiral in top view, and a lead-out wire that has one end portion connected to one end portion of the lower element, for example. In the signal transmission device, the breakdown voltage holding insulating film is disposed in a region inside the lead-out wire in a direction of extension of the lead-out wire.

The signal transmission device disclosed in Japanese Patent Application Laid-Open No. 2008-218121 has a structure in which the breakdown voltage holding insulating film is formed only in a region in which the lower element is disposed and thus has a step of several tens of micrometers at a boundary between a region in which the breakdown voltage holding insulating film is formed and a region in which the breakdown voltage holding insulating film is not formed. There is a need for consideration of the step in a process of photoengraving, etching, or the like to form the upper element after formation of the breakdown voltage holding insulating film, so that it has been difficult to perform the process.

Furthermore, an electrode pad as one end portion of the upper element is subjected to wire bonding, and, in this case, a downward load and lateral vibration are applied to the electrode pad to improve adhesion between a wire and the electrode pad. In a case where the electrode pad has a small thickness, the impact of such wire bonding is not cushioned, and cracking of the electrode pad and the insulating film below the electrode pad is of concern.

### SUMMARY

It is an object of the present disclosure to provide technology enabling easy formation of an upper element and a structure to cushion the impact of wiring bonding on an electrode pad as one end portion of the upper element.

A semiconductor device according to the present disclosure includes a substrate, a breakdown voltage holding insulating film, an element portion, a lead-out wire, a first electrode pad, a second electrode pad, and a top layer protective film. The breakdown voltage holding insulating film is disposed on a side of an upper surface of the substrate. The element portion includes a lower element that is disposed in the breakdown voltage holding insulating film and is spiral in top view and the upper element that is disposed above the lower element in the breakdown voltage holding insulating film and is spiral in top view. The lead-out wire has one end portion connected to one end portion of the lower element. The first electrode pad is connected to the other end portion of the lead-out wire. The second electrode pad is located opposite the one end portion of the lower element and is one end portion of the upper element. The top layer protective film has an opening above the second electrode pad and covers the upper element so that the second electrode pad is exposed from the opening. The breakdown voltage holding insulating film and the top layer protective film extend to a region outside the first electrode pad in a direction of extension of the lead-out wire. An electrically conductive pad double stack portion is disposed on an upper surface of the second electrode pad. The top layer protective film covers a peripheral portion of the pad double stack portion.

Since the breakdown voltage holding insulating film extends to the region outside the first electrode pad in the direction of extension of the lead-out wire, there is no step in a region of the breakdown voltage holding insulating film in which the upper element is formed and a region around the region. This eliminates the need for consideration of the step in a process of forming the upper element to facilitate formation of the upper element.

Furthermore, the pad double stack portion on the upper surface of the second electrode pad eliminates the need for a change in thickness of the upper element to facilitate formation of a structure to cushion the impact of wire bonding on the second electrode pad as the one end portion of the upper element.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor device according to Embodiment 1;

FIG. 2 is a cross-sectional view taken along the line A-A of FIG. 1;

FIG. 3 is a flowchart showing a method of manufacturing the semiconductor device according to Embodiment 1;

FIG. 4 is a cross-sectional view for describing the method of manufacturing the semiconductor device according to Embodiment 1;

FIG. 5 is a cross-sectional view for describing the method of manufacturing the semiconductor device according to Embodiment 1;

FIG. 6 is a cross-sectional view for describing the method of manufacturing the semiconductor device according to Embodiment 1;

FIG. 7 is a cross-sectional view for describing the method of manufacturing the semiconductor device according to Embodiment 1;

FIG. 8 is a cross-sectional view for describing the method of manufacturing the semiconductor device according to Embodiment 1;

FIG. 9 is a cross-sectional view for describing the method of manufacturing the semiconductor device according to Embodiment 1;

FIG. 10 is a cross-sectional view for describing the method of manufacturing the semiconductor device according to Embodiment 1;

FIG. 11 is a cross-sectional view for describing the method of manufacturing the semiconductor device according to Embodiment 1;

FIG. 12 is a top view of a semiconductor device according to Embodiment 2; and

FIG. 13 is a cross-sectional view taken along the line B-B of FIG. 12.

### DESCRIPTION OF THE PREFERRED EMBODIMENTS

### Embodiment 1

### <Structure of Semiconductor Device>

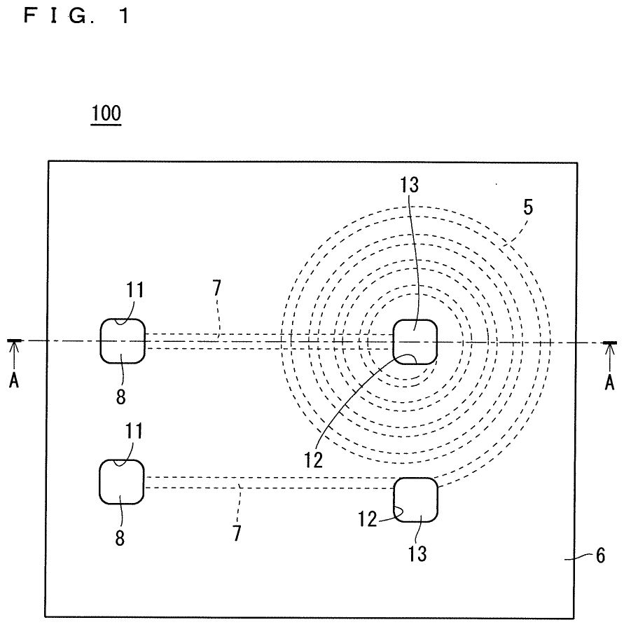

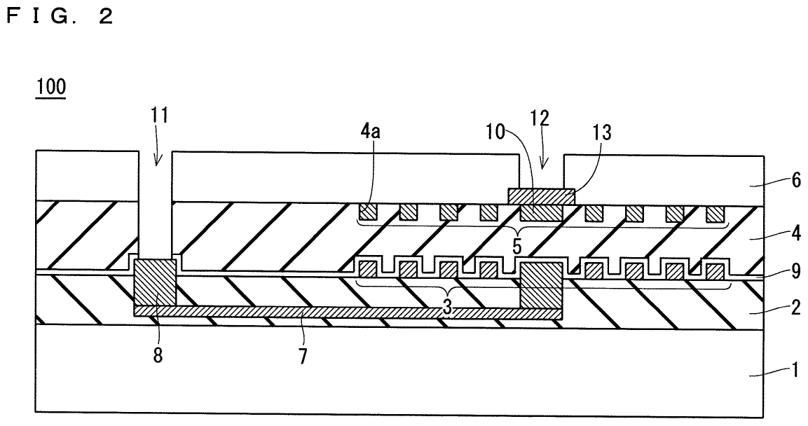

Embodiment 1 will be described below with reference to the drawings. FIG. 1 is a top view of a semiconductor device 100 according to Embodiment 1. FIG. 2 is a cross-sectional view taken along the line A-A of FIG. 1.

As illustrated in FIGS. 1 and 2, the semiconductor device 100 includes a substrate 1, an insulating film 2, lead-out wires 7, a lower element 3, first electrode pads 8, a breakdown voltage holding insulating film 4, an upper element 5, second electrode pads 10, pad double stack portions 13, and a top layer protective film 6.

The substrate 1 may be a semiconductor substrate of Si, SiC, GaN, or the like, or may be an insulating substrate of glass, ceramics, or the like.

The insulating film 2 is disposed across an upper surface of the substrate 1. The insulating film 2 is an oxide film or a nitride film as a typical semiconductor material.

The breakdown voltage holding insulating film 4 is disposed across an upper surface of the insulating film 2 on a side of the upper surface of the substrate 1. The breakdown voltage holding insulating film 4 is a silicon oxide film, a silicon nitride film, or a polyimide film of an organic material.

The lower element 3 is a lower coil element formed to be spiral in top view and is disposed on the upper surface of the insulating film 2 in the breakdown voltage holding insulating film 4. The lower element 3 is disposed in a right region in the breakdown voltage holding insulating film 4 in each of FIGS. 1 and 2.

A central portion of the spiral of the lower element 3 (one end portion of the lower element 3) is connected to one end portion of one of the lead-out wires 7. The one of the lead-out wires 7 extends leftward from the central portion of the spiral of the lower element 3 in each of FIGS. 1 and 2. The other end portion of the one of the lead-out wires 7 is connected to one of the first electrode pads 8.

The other end portion of the spiral of the lower element 3 is connected to one end portion of the other one of the lead-out wires 7. The other one of the lead-out wires 7 extends leftward from the other end portion of the spiral of the lower element 3 in each of FIGS. 1 and 2. The other end portion of the other one of the lead-out wires 7 is connected to the other one of the first electrode pads 8.

A protective film 9 of a different material from the breakdown voltage holding insulating film 4 may be disposed on upper surfaces of the lower element 3, the first electrode pads 8, and the insulating film 2 to improve an insulation breakdown voltage. The protective film 9 is a silicon oxide film or a silicon nitride film.

A groove 4a that is spiral in top view is formed in an upper surface of the breakdown voltage holding insulating film 4, and the upper element 5 as an upper coil element that is spiral in top view is disposed in the groove 4a. That is to say, the upper element 5 is disposed above the lower element 3 in the breakdown voltage holding insulating film 4.

Due to signal transmission provided by magnetic coupling between the lower element 3 and the upper element 5, a high voltage is applied across the lower element 3 and the upper element 5, so that a desired breakdown voltage can be obtained in the breakdown voltage holding insulating film 4 by adjusting the thickness of the breakdown voltage holding insulating film 4. As described above, the lower element 3 and the upper element 5 constitute a coil element as an element portion.

The upper element 5 has the second electrode pads 10 in opposite end portions thereof. The pad double stack portions 13 that are electrically conductive are arranged on upper surfaces of the second electrode pads 10. The second electrode pads 10 are subjected to wire bonding, and, in this case, downward loads and lateral vibration are applied to the second electrode pads 10 to improve adhesion between wires and the second electrode pads 10. In a case where the second electrode pads 10 each have a small thickness, the impact of such wire bonding is not cushioned, and cracking of the second electrode pads 10 and the breakdown voltage holding insulating film 4 below the second electrode pads 10 is of concern. The pad double stack portions 13 are arranged to cushion the impact of wire bonding.

An increase in thickness of each of the second electrode pads 10 without arranging the pad double stack portions 13 is conceivable but affects device characteristics, so that it is necessary to increase the thickness of each of the second electrode pads 10 without changing the thickness of a portion of the upper element 5 other than the second electrode pads 10. It has thus been difficult to increase the thickness of each of the second electrode pads 10. The pad double stack portions 13 allow for cushioning of the impact of wire bonding without changing the thickness of the upper element 5.

A top view outline of each of the pad double stack portions 13 may herein be larger than a top view outline of each of the second electrode pads 10. Furthermore, the top layer protective film 6, which will be described below, is formed to cover a peripheral portion of each of the pad double stack portions 13 in this stricture to make the pad double stack portions 13 less likely to be removed during wire bonding.

As described above, the upper element 5 is disposed in the groove 4a of the breakdown voltage holding insulating film 4. That is to say, the upper element 5 is embedded in the groove 4a of the breakdown voltage holding insulating film 4, so that the upper surface of the breakdown voltage holding insulating film 4 and an upper surface of the upper element 5 are at the same level within the margin of manufacturing error. Since they are at the same level, the top view outline of each of the pad double stack portions 13 can be larger than the top view outline of each of the second electrode pads 10 with an upper surface of each of the pad double stack portions 13 being flat.

The top layer protective film 6 forming a top portion of the semiconductor device 100 is disposed on the upper surfaces of the upper element 5 and the breakdown voltage holding insulating film 4. The top layer protective film 6 is a silicon nitride film or a polyimide film.

First contact holes 11 are formed above the first electrode pads 8 in the top layer protective film 6 and the breakdown voltage holding insulating film 4. Second contact holes 12 (openings) are formed in the top layer protective film 6 above the second electrode pads 10, that is, in the top layer protective film 6 at positions corresponding to the pad double stack portions 13. In this case, a top view outline of each of the second contact holes 12 is smaller than the top view outline of each of the pad double stack portions 13.

### <Semiconductor Device Manufacturing Method>

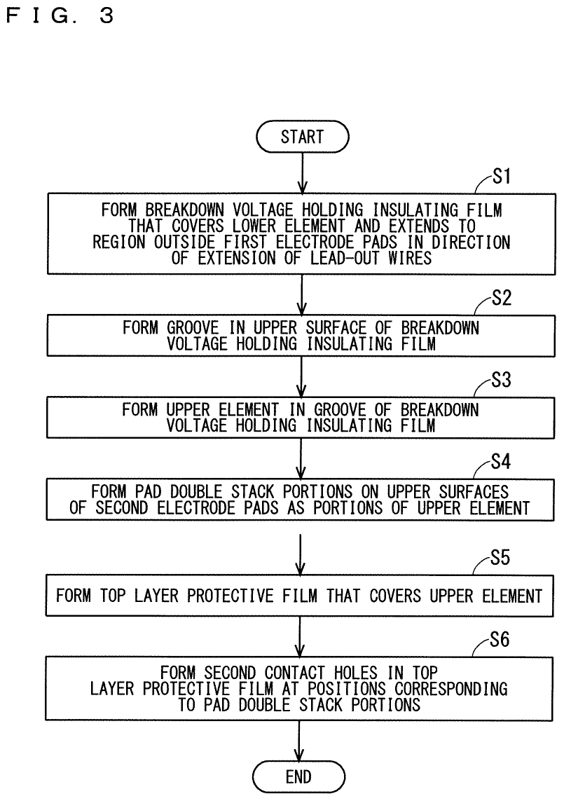

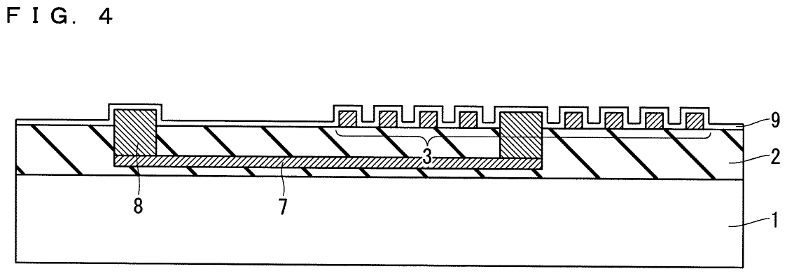

A method of manufacturing the semiconductor device 100 will be described next with reference to FIGS. 3 to 11. FIG. 3 is a flowchart showing the method of manufacturing the semiconductor device 100 according to Embodiment 1 and is, specifically, a flowchart showing a process from formation of the breakdown voltage holding insulating film 4 to formation of the second contact holes 12. FIGS. 4 to 11 are cross-sectional views for describing the method of manufacturing the semiconductor device 100 according to Embodiment 1.

First, as illustrated in FIG. 4, after the insulating film 2 is formed on the substrate 1 by CVD or SOG, the lead-out wires 7 extending from the lower element 3 are formed by metal film formation by sputtering or vapor deposition, photoengraving, or etching.

After the insulating film 2 is formed again, and the first electrode pads 8 connected to the lead-out wires 7 are formed in the insulating film 2 by etching, the lower element 3 is formed. The lower element 3 is formed by metal film formation by sputtering or vapor deposition, photoengraving, or etching. The protective film 9 is then formed on an upper side of the lower element 3 by CVD or SOG.

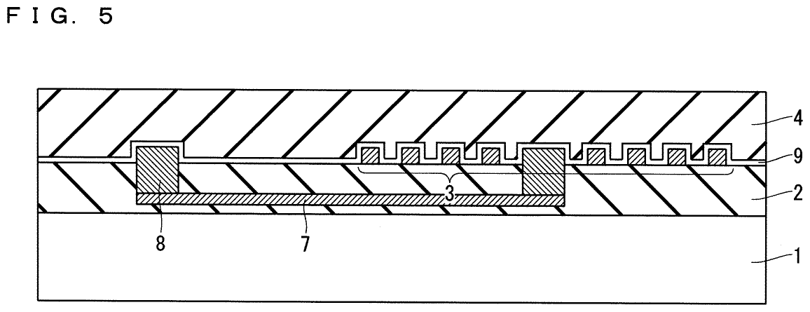

Next, as illustrated in FIG. 5, the breakdown voltage holding insulating film 4 is formed to cover the lower element 3 and extend to a region outside the first electrode pads 8 in a direction of extension of the lead-out wires 7 (step S1). In a case where the breakdown voltage holding insulating film 4 is a silicon oxide film or a silicon nitride film, the breakdown voltage holding insulating film 4 is formed by CVD or SOG. In a case where the breakdown voltage holding insulating film 4 is a polyimide film, the breakdown voltage holding insulating film 4 is formed by a method such as spin coating and spray coating.

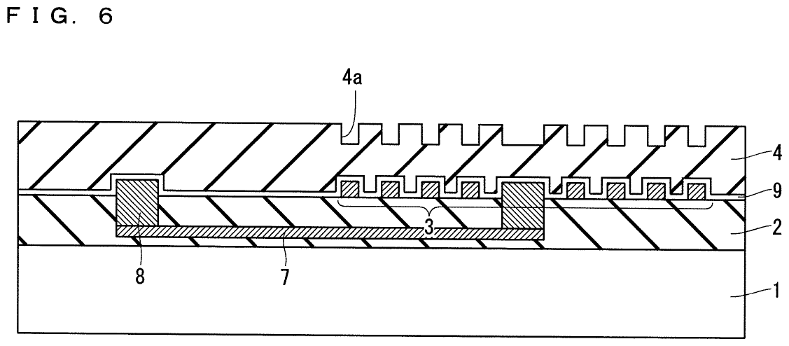

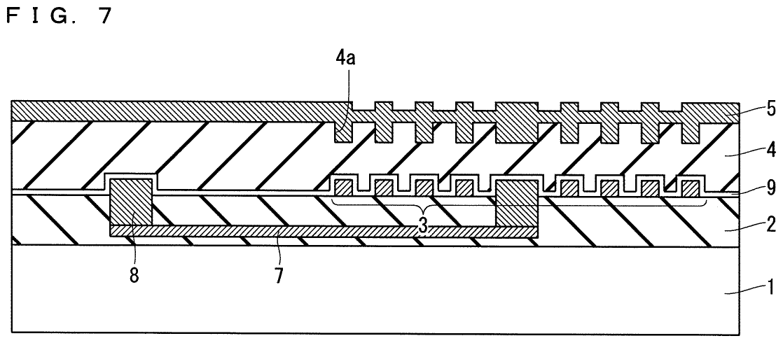

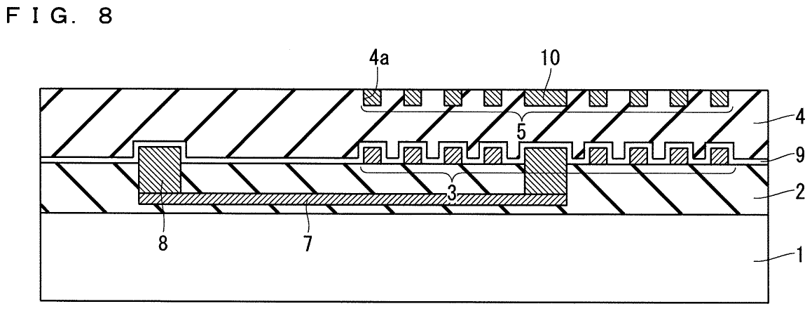

Next, the groove 4a is formed in the breakdown voltage holding insulating film 4, and the upper element 5 is formed in the groove 4a by a damascene method. This is now described. First, as illustrated in FIG. 6, the groove 4a having the same shape as the upper element 5 is formed in the upper surface of the breakdown voltage holding insulating film 4 by etching (step S2). Then, as illustrated in FIG. 7, a metal film to be the upper element 5 is formed on the upper surface of the breakdown voltage holding insulating film 4 by sputtering and vapor deposition. As illustrated in FIG. 8, a surface of the metal film is further planarized by CMP or etchback to form the upper element 5 in the groove 4a of the breakdown voltage holding insulating film 4 (step S3).

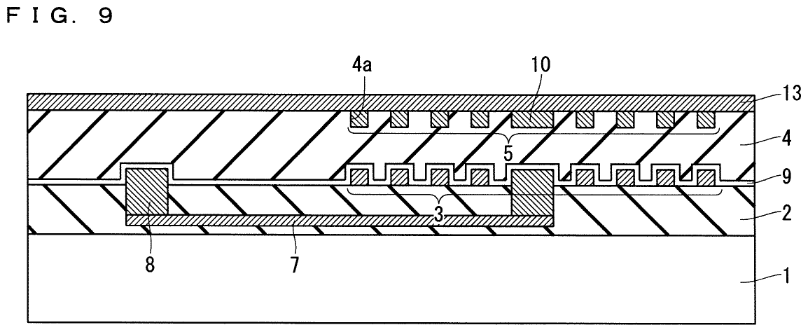

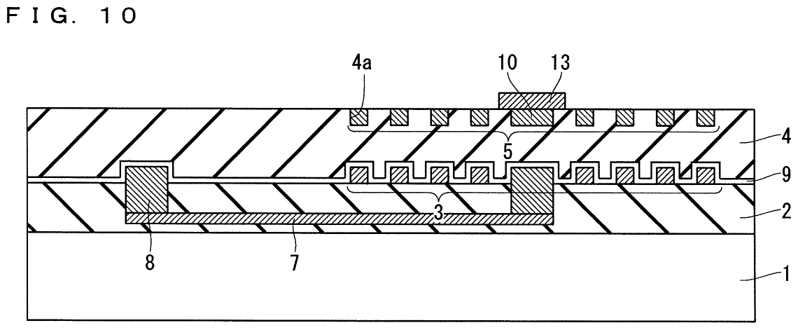

Next, as illustrated in FIG. 9, a metal film to be the pad double stack portions 13 is formed on the upper surface of the breakdown voltage holding insulating film 4 by sputtering and vapor deposition. As illustrated in FIG. 10, the pad double stack portions 13 are formed on the upper surfaces of the second electrode pads 10 as portions of the upper element 5 by photoengraving or etching (step S4).

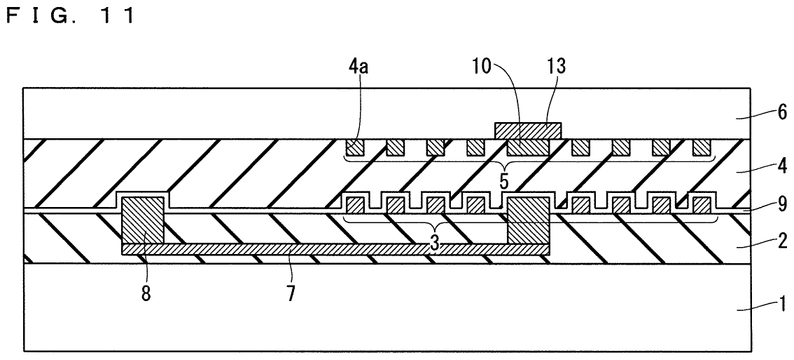

Next, as illustrated in FIG. 11, the top layer protective film 6 is formed to cover the upper element 5 (step S5). In a case where the top layer protective film 6 is a silicon nitride film, the top layer protective film 6 is formed by CVD or SOG. In a case where the top layer protective film 6 is polyimide, the top layer protective film 6 is formed by spin coating or spray coating.

Finally, the first contact holes 11 are formed in the top layer protective film 6 at positions corresponding to the first electrode pads 8, and the second contact holes 12 are formed in the top layer protective film 6 at the positions corresponding to the pad double stack portions 13 (step S6). Specifically, the first contact holes 11 and the second contact holes 12 are opened by etching to obtain the final structure of the semiconductor device 100 illustrated in FIG. 2.

### Effects

As described above, the semiconductor device 100 according to Embodiment 1 includes: the substrate 1; the breakdown voltage holding insulating film 4 that is disposed on a side of the upper surface of the substrate 1; the element portion including the lower element 3 that is disposed in the breakdown voltage holding insulating film 4 and is spiral in top view and the upper element 5 that is disposed above the lower element 3 in the breakdown voltage holding insulating film 4 and is spiral in top view; the lead-out wires 7 that each have one end portion connected to an end portion of the lower element 3; the first electrode pads 8 that are each connected to the other end portion of each of the lead-out wires 7; the second electrode pads 10 that are each located opposite the end portion of the lower element 3 and are each an end portion of the upper element 5; and the top layer protective film 6 that has the second contact holes 12 above the second electrode pads 10 and covers the upper element 5 so that the second electrode pads 10 are exposed from the second contact holes 12. The breakdown voltage holding insulating film 4 and the top layer protective film 6 extend to the region outside the first electrode pads 8 in the direction of extension of the lead-out wires 7. The electrically conductive pad double stack portions 13 are arranged on the upper surfaces of the second electrode pads 10. The top layer protective film 6 covers the peripheral portion of each of the pad double stack portions 13.

Since the breakdown voltage holding insulating film 4 extends to the region outside the first electrode pads 8 in the direction of extension of the lead-out wires 7, there is no step in a region of the breakdown voltage holding insulating film 4 in which the upper element 5 is formed and a region around the region. This eliminates the need for consideration of the step in a process of forming the upper element 5 to facilitate formation of the upper element 5.

Furthermore, the pad double stack portions 13 on the upper surfaces of the second electrode pads 10 eliminate the need for a change in thickness of the upper element 5 to facilitate formation of a structure to cushion the impact of wire bonding on the second electrode pads 10 each as the end portion of the upper element 5.

The method of manufacturing the semiconductor device 100 according to Embodiment 1 includes: forming, after forming the lead-out wires 7 on a side of the upper surface of the substrate 1, the lower element 3 that has end portions each connected to one end portion of each of the lead-out wires 7 and is spiral in top view and the first electrode pads 8 that are each connected to the other end portion of each of the lead-out wires 7; forming the breakdown voltage holding insulating film 4 that covers the lower element 3 and extends to the region outside the first electrode pads 8 in the direction of extension of the lead-out wires 7; forming, in the upper surface of the breakdown voltage holding insulating film 4, the groove 4a that is spiral in top view; forming, in the groove 4a of the breakdown voltage holding insulating film 4, the upper element 5 that is spiral in top view; forming the pad double stack portions 13 on the upper surfaces of the second electrode pads 10 as the portions of the upper element 5; forming the top layer protective film 6 to cover the upper element 5; and forming the second contact holes 12 in the top layer protective film 6 at the positions corresponding to the pad double stack portions 13.

Since the upper element 5 is formed in the groove 4a of the breakdown voltage holding insulating film 4, the upper surfaces of the breakdown voltage holding insulating film 4 and the upper element 5 are flat to facilitate formation of the pad double stack portions 13.

Since the top view outline of each of the pad double stack portions 13 is larger than the top view outline of each of the second electrode pads 10, the area of contact between the pad double stack portions 13 and portions of the breakdown voltage holding insulating film 4 around the second electrode pads 10 can be increased. An effect of cushioning the impact of wire bonding can thereby further be improved.

### Embodiment 2

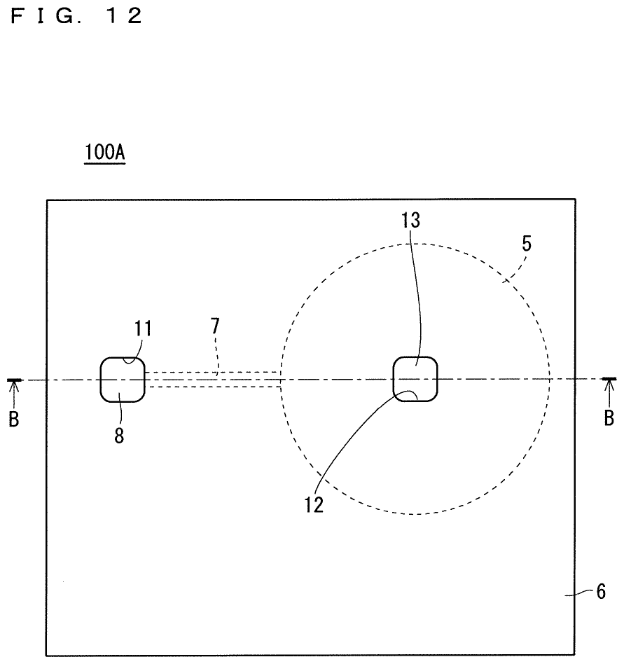

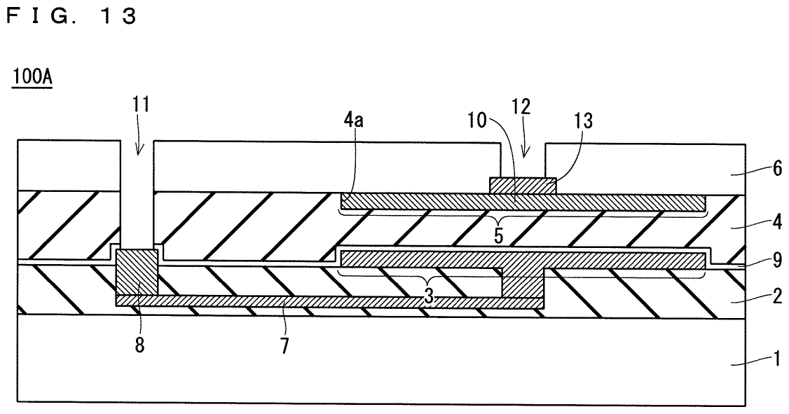

A semiconductor device 100A according to Embodiment 2 will be described next. FIG. 12 is a top view of the semiconductor device 100A according to Embodiment 2. FIG. 13 is a cross-sectional view taken along the line B-B of FIG. 12. In Embodiment 2, the same components as those described in Embodiment 1 bear the same reference signs as those of the same components, and description thereof will be omitted.

While the upper element 5 and the lower element 3 are each a spiral coil element in top view in Embodiment 1, the upper element 5 and the lower element 3 are each a circular flat plate in top view in Embodiment 2 as illustrated in FIGS. 12 and 13. The lower element 3 and the upper element 5 constitute a flat plate capacitor as the element portion. Embodiment 2 differs from Embodiment 1 in that the groove 4a of the breakdown voltage holding insulating film 4 is formed to be circular in top view and a second electrode pad 10 and a pad double stack portion 13 are formed only in a central portion of the upper element 5.

A method of manufacturing the semiconductor device 100A according to Embodiment 2 is similar to that in a case of Embodiment 1, so that description thereof is omitted.

As described above, the semiconductor device 100A according to Embodiment 2 includes: the substrate 1; the breakdown voltage holding insulating film 4 that is disposed on a side of the upper surface of the substrate 1; the element portion including the lower element 3 that is disposed in the breakdown voltage holding insulating film 4 and is circular in top view and the upper element 5 that is disposed above the lower element 3 in the breakdown voltage holding insulating film 4 and is circular in top view; a lead-out wire 7 that has one end portion connected to a central portion of the lower element 3; a first electrode pad 8 that is connected to the other end portion of the lead-out wire 7; the second electrode pad 10 that is located opposite the central portion of the lower element 3 and is the central portion of the upper element 5; and the top layer protective film 6 that has a second contact hole 12 above the second electrode pad 10 and covers the upper element 5 so that the second electrode pad 10 is exposed from the second contact hole 12. The breakdown voltage holding insulating film 4 and the top layer protective film 6 extend to a region outside the first electrode pad 8 in a direction of extension of the lead-out wire 7. An electrically conductive pad double stack portion 13 is disposed on an upper surface of the second electrode pad 10. The top layer protective film 6 covers a peripheral portion of the pad double stack portion 13.

The method of manufacturing the semiconductor device 100A according to Embodiment 2 includes: forming, after forming the lead-out wire 7 on a side of the upper surface of the substrate 1, the lower element 3 that has the central portion connected to the one end portion of the lead-out wire 7 and is circular in top view and the first electrode pad 8 that is connected to the other end portion of the lead-out wire 7; forming the breakdown voltage holding insulating film 4 that covers the lower element 3 and extends to the region outside the first electrode pad 8 in the direction of extension of the lead-out wire 7; forming, in the upper surface of the breakdown voltage holding insulating film 4, the groove 4a that is circular in top view; forming, in the groove 4a of the breakdown voltage holding insulating film 4, the upper element 5 that is circular in top view; forming the pad double stack portion 13 on the upper surface of the second electrode pad 10 as a portion of the upper element 5; forming the top layer protective film 6 to cover the upper element 5; and forming the second contact hole 12 in the top layer protective film 6 at a position corresponding to the pad double stack portion 13.

An effect similar to that obtained in a case of Embodiment 1 can thus be obtained.

Embodiments can freely be combined with each other and can be modified or omitted as appropriate.

Various aspects of the present disclosure will collectively be described below as appendices.

### (Appendix 1)

A semiconductor device comprising:
a substrate;
a breakdown voltage holding insulating film that is disposed on a side of an upper surface of the substrate;
an element portion that includes a lower element and an upper element, the lower element being disposed in the breakdown voltage holding insulating film and being spiral in top view, the upper element being disposed above the lower element in the breakdown voltage holding insulating film and being spiral in top view;
a lead-out wire that has one end portion connected to one end portion of the lower element;
a first electrode pad that is connected to the other end portion of the lead-out wire;
a second electrode pad that is located opposite the one end portion of the lower element and is one end portion of the upper element; and
a top layer protective film that has an opening above the second electrode pad and covers the upper element so that the second electrode pad is exposed from the opening, wherein
the breakdown voltage holding insulating film and the top layer protective film extend to a region outside the first electrode pad in a direction of extension of the lead-out wire,
an electrically conductive pad double stack portion is disposed on an upper surface of the second electrode pad, and
the top layer protective film covers a peripheral portion of the pad double stack portion.

### (Appendix 2)

A semiconductor device comprising:
a substrate;
a breakdown voltage holding insulating film that is disposed on a side of an upper surface of the substrate;
an element portion that includes a lower element and an upper element, the lower element being disposed in the breakdown voltage holding insulating film and being circular in top view, the upper element being disposed above the lower element in the breakdown voltage holding insulating film and being circular in top view;
a lead-out wire that has one end portion connected to a central portion of the lower element;
a first electrode pad that is connected to the other end portion of the lead-out wire;
a second electrode pad that is located opposite the central portion of the lower element and is a central portion of the upper element; and
a top layer protective film that has an opening above the second electrode pad and covers the upper element so that the second electrode pad is exposed from the opening, wherein
the breakdown voltage holding insulating film and the top layer protective film extend to a region outside the first electrode pad in a direction of extension of the lead-out wire,
an electrically conductive pad double stack portion is disposed on an upper surface of the second electrode pad, and
the top layer protective film covers a peripheral portion of the pad double stack portion.

### (Appendix 3)

The semiconductor device according to Appendix 1 or 2, wherein
a top view outline of the pad double stack portion is larger than a top view outline of the second electrode pad.

### (Appendix 4)

A semiconductor device manufacturing method comprising:
forming, after forming a lead-out wire on a side of an upper surface of a substrate, a lower element and a first electrode pad, the lower element having one end portion connected to one end portion of the lead-out wire and being spiral in top view, the first electrode pad being connected to the other end portion of the lead-out wire;
forming a breakdown voltage holding insulating film that covers the lower element and extends to a region outside the first electrode pad in a direction of extension of the lead-out wire;
forming, in an upper surface of the breakdown voltage holding insulating film, a groove that is spiral in top view;
forming, in the groove of the breakdown voltage holding insulating film, an upper element that is spiral in top view;
forming a double stack portion on an upper surface of a second electrode pad as a portion of the upper element;
forming a top layer protective film to cover the upper element; and
forming an opening in the top layer protective film at a position corresponding to the double stack portion.

### (Appendix 5)

A semiconductor device manufacturing method comprising:
forming, after forming a lead-out wire on a side of an upper surface of a substrate, a lower element and a first electrode pad, the lower element having a central portion connected to one end portion of the lead-out wire and being circular in top view, the first electrode pad being connected to the other end portion of the lead-out wire; forming a breakdown voltage holding insulating film that covers the lower element and extends to a region outside the first electrode pad in a direction of extension of the lead-out wire;
forming, in an upper surface of the breakdown voltage holding insulating film, a groove that is circular in top view;
forming, in the groove of the breakdown voltage holding insulating film, an upper element that is circular in top view;
forming a double stack portion on an upper surface of a second electrode pad as a portion of the upper element;
forming a top layer protective film to cover the upper element; and
forming an opening in the top layer protective film at a position corresponding to the double stack portion.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a substrate;
a breakdown voltage holding insulating film that is disposed on a side of an upper surface of the substrate;
an element portion that includes a lower element and an upper element, the lower element being disposed in the breakdown voltage holding insulating film and being spiral in top view, the upper element being disposed above the lower element in the breakdown voltage holding insulating film and being spiral in top view;
a lead-out wire that has one end portion connected to one end portion of the lower element;
a first electrode pad that is connected to the other end portion of the lead-out wire;
a second electrode pad that is located opposite the one end portion of the lower element and is one end portion of the upper element; and
a top layer protective film that has an opening above the second electrode pad and covers the upper element so that the second electrode pad is exposed from the opening, wherein
the breakdown voltage holding insulating film and the top layer protective film extend to a region outside the first electrode pad in a direction of extension of the lead-out wire,
an electrically conductive pad double stack portion is disposed on an upper surface of the second electrode pad, and
the top layer protective film covers a peripheral portion of the pad double stack portion.

2. A semiconductor device comprising:
a substrate;
a breakdown voltage holding insulating film that is disposed on a side of an upper surface of the substrate;
an element portion that includes a lower element and an upper element, the lower element being disposed in the breakdown voltage holding insulating film and being circular in top view, the upper element being disposed above the lower element in the breakdown voltage holding insulating film and being circular in top view;
a lead-out wire that has one end portion connected to a central portion of the lower element;
a first electrode pad that is connected to the other end portion of the lead-out wire;
a second electrode pad that is located opposite the central portion of the lower element and is a central portion of the upper element; and
a top layer protective film that has an opening above the second electrode pad and covers the upper element so that the second electrode pad is exposed from the opening, wherein
the breakdown voltage holding insulating film and the top layer protective film extend to a region outside the first electrode pad in a direction of extension of the lead-out wire,
an electrically conductive pad double stack portion is disposed on an upper surface of the second electrode pad, and
the top layer protective film covers a peripheral portion of the pad double stack portion.

3. The semiconductor device according to claim 1, wherein
a top view outline of the pad double stack portion is larger than a top view outline of the second electrode pad.

4. The semiconductor device according to claim 2, wherein
a top view outline of the pad double stack portion is larger than a top view outline of the second electrode pad.

5. A semiconductor device manufacturing method comprising:
forming, after forming a lead-out wire on a side of an upper surface of a substrate, a lower element and a first electrode pad, the lower element having one end portion connected to one end portion of the lead-out wire and being spiral in top view, the first electrode pad being connected to the other end portion of the lead-out wire;
forming a breakdown voltage holding insulating film that covers the lower element and extends to a region outside the first electrode pad in a direction of extension of the lead-out wire;
forming, in an upper surface of the breakdown voltage holding insulating film, a groove that is spiral in top view;
forming, in the groove of the breakdown voltage holding insulating film, an upper element that is spiral in top view;
forming a double stack portion on an upper surface of a second electrode pad as a portion of the upper element;
forming a top layer protective film to cover the upper element; and
forming an opening in the top layer protective film at a position corresponding to the double stack portion.

6. A semiconductor device manufacturing method comprising:
forming, after forming a lead-out wire on a side of an upper surface of a substrate, a lower element and a first electrode pad, the lower element having a central portion connected to one end portion of the lead-out wire and being circular in top view, the first electrode pad being connected to the other end portion of the lead-out wire;
forming a breakdown voltage holding insulating film that covers the lower element and extends to a region outside the first electrode pad in a direction of extension of the lead-out wire;
forming, in an upper surface of the breakdown voltage holding insulating film, a groove that is circular in top view;
forming, in the groove of the breakdown voltage holding insulating film, an upper element that is circular in top view;
forming a double stack portion on an upper surface of a second electrode pad as a portion of the upper element;
forming a top layer protective film to cover the upper element; and
forming an opening in the top layer protective film at a position corresponding to the double stack portion.
